(19) United States
(12) Patent Application Publication
(10) Pub. No.: US 2005/0083755 A1
(43) Pub. Date: Apr. 21, 2005

(54) Flash memory system and method

(75) Inventor: Byoung-Joon Choi, Seoul (KR)

Correspondence Address: JONATHAN Y. KANG, ESQ.;LEE, HONG, DEGERMAN, KANG & SCHMADEKA, P.C., 14th Floor, 801 S. Figueroa Street, Los Angeles, CA, 90017-5554, US

(73) Assignee: LG Electronics Inc.

(21) Appl. No.: 10/970,285

(22) Filed: Oct. 20, 2004

(30) Foreign Application Priority Data
Oct. 20, 2003 (KR) 10-2003-0073125

(51) Int. Cl. G11C 7/00

(52) U.S. Cl. 365/222

(57) ABSTRACT

A method and system directed to a memory device is provided. The memory device reads and writes multimedia data and supplementary application data of a mobile terminal. The memory device comprises a processor for generating a read message or a write message, a dual-port random access memory, a NAND-TYPE flash memory, and a programmable logic device. The memory device transfers data stored in the NAND-TYPE flash memory to the dual=port random access memory on the basis of the read message.

### CROSS-REFERENCE TO RELATED APPLICATIONS

Pursuant to 35 U.S.C. § 119(a), this application claims the benefit of earlier filing date and right of priority to Korean Application No. 10-2003-0073125, filed on Oct. 20, 2003, the contents of which are hereby incorporated by reference herein in their entirety.

### BACKGROUND OF THE INVENTION

1. Field of the Invention

The present invention relates to a flash memory system and method, and more particularly to a NAND-TYPE flash memory system and method.

2. Description of the Related Art

There are many memory devices available to store data. Memory devices include read only memory (ROM), electronically erasable read only memory (EEPROMs), and flash memory devices. ROMS are nonvolatile memory for maintaining data while a unit, such as a digital camera, computer, or an MP3 player, is in a power-off mode. EEPROMS provide a user with the opportunity to program memory to perform a specific purpose.

Flash memory is a form of EEPROM that allows multiple memory locations to be erased or written in one programming operation. Flash memory stores information in an array of transistors, called cells, each of which traditionally stores one bit of information. Flash memory performs an operation, such as an erase, in a block, sector or chip unit.

Flash memory comes in many forms such as NOR-TYPE and NAND-TYPE, which designation refers to the type of logic gate used for each memory cell. NOR-TYPE flash memory connects memory cells in parallel between a bit line and a ground line. NOR-TYPE flash memory performs an address decoding process for a read or a write instruction in the similar manner to a dynamic random access memory (DRAM).

NOR-TYPE flash memory simplifies the requirement for peripheral circuits. NOR-TYPE flash memory requires a contact electrode of a bit line in each cell, which requirement results in NOR-TYPE flash memory occupying a larger cell area than a NAND-TYPE flash memory for the same memory size.

In contrast to NOR-TYPE flash memory, NAND-TYPE flash memory has memory cells serially connected between a bit line and a ground line. NAND-TYPE flash memory has a high operational resistance, which is proportional to the number of serially connected cells, resulting in lower reading speed and reduced data accessing efficiency than NOR-TYPE flash memory cells. NAND-TYPE flash memory has the capability for high integration capacity resulting in handling gigabit data packets.

FIGS. 1A and 1B are block diagrams illustrating prior art NAND-TYPE flash memory write operation (FIG. 1A) and read operation (FIG. 1B).

NAND-TYPE flash memory 105 includes a processor 100, a NAND-TYPE flash memory 105, and a command/address/data multiplexing input/output port 110. The processor 100 transmits information including executable commands, addresses, and data through a data bus 115. This transfer of information increases data bus 115 loading and data accessing time. The information on the data bus 115 is identified by a control signal from a general purpose input output interface (GPIO) 120.

FIG. 2 is a block diagram illustrating a data write operation from the prior art for a NAND-TYPE flash memory. A processor 210 reads the information (commands, addresses and data (DATA 0, DATA 1, . . . ) from a read only memory (ROM). The information is stored in a random access memory (RAM). The processor 210 reads the information from the RAM, and transmits the information to the NAND-TYPE flash memory 105 via the data bus 115. The NAND-TYPE flash memory 105 stores the data in memory locations designated addresses.

FIG. 3 is a block diagram illustrating the data read operation of the conventional NAND-TYPE flash memory. The processor 210 reads information (for example commands, addresses and data) from the ROM, and stores the information in the RAM. The processor 210 reads the information stored in the RAM. The processor 210 transmits the information to the NAND-TYPE flash memory 105 via the data bus 115. The NAND-TYPE flash memory 105 reads the data from a location designated by the addresses and stores the data in the RAM.

When the processor 210 transmits the information to the NAND-TYPE flash memory via the data bus, the processor 210 must access the ROM and the RAM. Thus, data read and/or write access time is increased. Other operations, such as data transfers, cannot be performed while prior art NAND-TYPE flash memory devices are accessing data.

NOR-TYPE flash memory is used in a mobile terminal because it occupies a smaller area than NAND-TYPE flash memory. Moreover, as compared with the NOR-TYPE structure, the NAND-TYPE structure requires a block selection step during a read operation. The block selection step increases the time for accessing data, and the load of the processor 210. Thus, there is a need for an improved memory device that provides improvements and solves problems presented by the prior art.

### SUMMARY OF THE INVENTION

A system and method for a memory device is provided. The memory device both reads and writes multimedia data and supplementary application data. The memory device is applicable to a mobile terminal resulting in reduced data accessing time and load on the processor. The memory device can also be used for a base station terminal.

In accordance with one embodiment, a first and a second memory are connected through an interface unit. The interface unit interprets messages (created by a processor) for increasing the speed of read and write data operations and data accessing time.

In accordance with one embodiment, the memory device has a processor for generating a read message or a write message, a dual-port random access memory (DPRAM), and a NAND-TYPE flash memory. A programmable logic device (PLD) stores data in the NAND-TYPE flash memory in the DPRAM based on the read message. The programmable logic device (PLD) stores data in, the DPRAM in the NAND-TYPE flash memory on the basis of the write message.

In accordance with another embodiment, the memory device is used in a mobile terminal has a processor for generating a read message or a write message, a first memory, and a second memory. An interface unit connected to the processor, the first memory, and the second memory allows transferring data between the first memory and the second memory. The interface unit interprets a message (containing commands, addresses, and data) sent from or to the processor, the first memory, and the second memory.

In accordance with another embodiment, the interface unit, after receiving a read message, transfers the data stored in the second memory to the first memory. In accordance with another embodiment, the interface unit, after receiving a write message, transfers the data stored in the first memory to the second memory.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings. The foregoing and other objects, features, aspects and advantages of the present invention will become more apparent from the following detailed description of the present invention when taken in conjunction with the accompanying drawings.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIGS. 1A and 1B are block diagrams illustrating data read and write operations of a prior art NAND-TYPE flash memory.

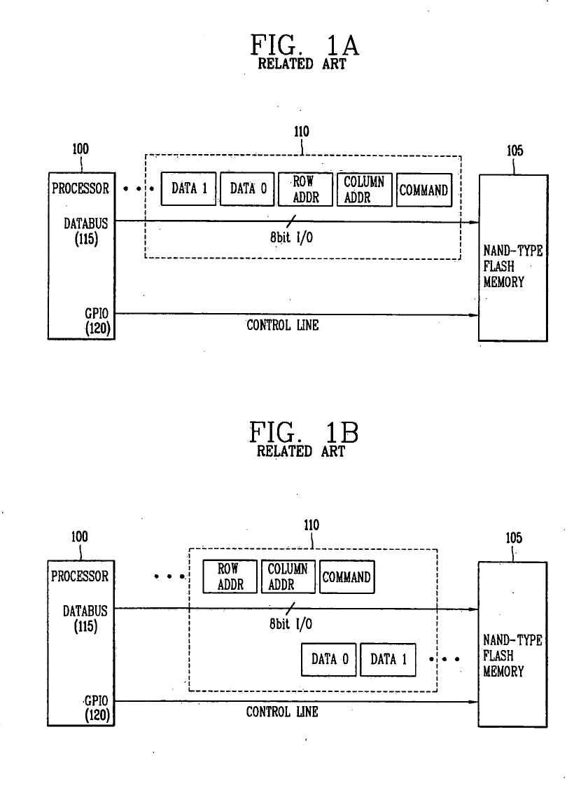

FIG. 2 is a block diagram illustrating the data write operation of the prior art NAND-TYPE flash memory.

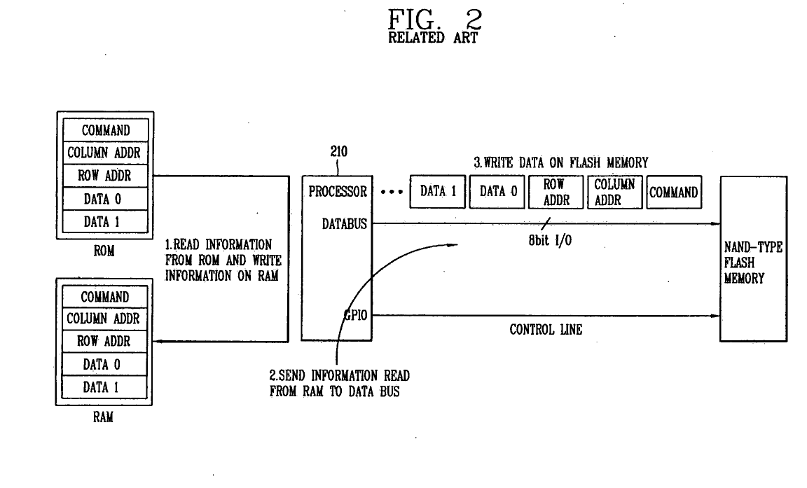

FIG. 3 is a block diagram illustrating the data read operation of the prior art NAND-TYPE flash memory.

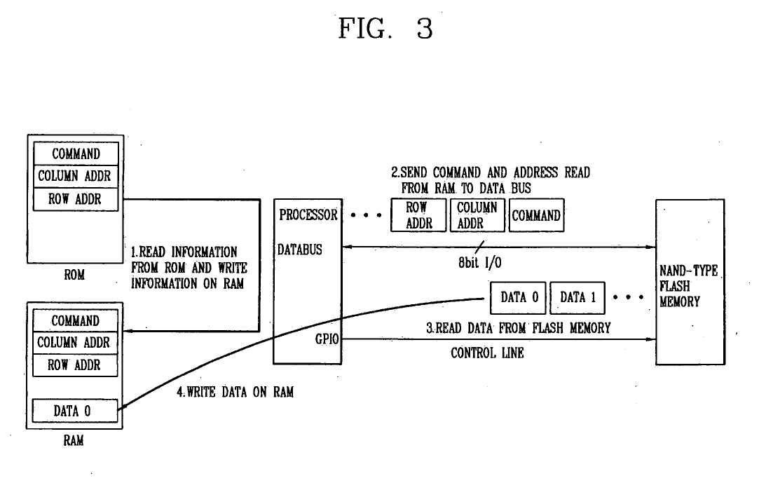

FIGS. 4A and 4B are block diagrams illustrating a NAND-TYPE flash memory device in accordance with an embodiment of the invention.

FIG. 5 is a block diagram illustrating the NAND-TYPE flash memory device in accordance with an embodiment of the invention.

FIG. 6 is a block diagram illustrating a programmable logic device of the NAND-TYPE flash memory device in accordance with an embodiment of the invention.

FIG. 7 is a block diagram illustrating a mobile communication device in accordance with an embodiment of the invention.

FIG. 8 is a block diagram illustrating a UTRAN in accordance with an embodiment of the invention.

Features, elements, and aspects of the invention that are referenced by the same numerals in different figures represent the same, equivalent, or similar features, elements, or aspects in accordance with one or more embodiments.

### DETAILED DESCRIPTION OF THE PREFERRED EMBODIMENTS

References are made in detail to the preferred embodiments of the present invention, examples of which are illustrated in the accompanying drawings. An apparatus for a flash memory device and method therefor in accordance with the preferred embodiments of the present invention will now be described in detail with reference to the accompanying drawings. Well-known functions or constructions are not described in detail since they would obscure the invention in unnecessary detail.

The invention has been described, by way of example, as applicable to a NAND-TYPE flash memory. However, it should be noted that other memory devices or their equivalents are applicable to this invention. The NAND-TYPE flash memory device of the present invention reduces accessing time and load on a processor for reading and writing data. The NAND-TYPE flash memory device easily reads and writes multimedia data and supplementary application data of a mobile terminal.

In accordance with one embodiment, a processor generates a read message or a write message. The read or the write message contains commands or instructions, addresses (for example, sending or receiving data), and data. The message is sent to a dual-port random access memory (DPRAM). A dual-port random access memory is a device which contents can be accessed in any order and allows multiple data read and write operations nearly simultaneously.

The message is transmitted to a NAND-TYPE flash memory, and a programmable logic device (PLD). NAND-TYPE flash memory refers to the type of logic gates and allows multiple locations to be read or written in the same programming step. The programmable logic device is a digital circuit with programmable logic circuit that provides combinational logic. The combinational logic controls the NAND-TYPE flash memory and the DPRAM, freeing the processor for performing other operations.

The programmable logic device interprets the read and the write message for determining, for example, a message destination. In one embodiment, the read message stored in the NAND-TYPE flash memory is transferred to the DPRAM. In yet another embodiment, the write message stored in the DPRAM is transferred to the NAND-TYPE flash memory.

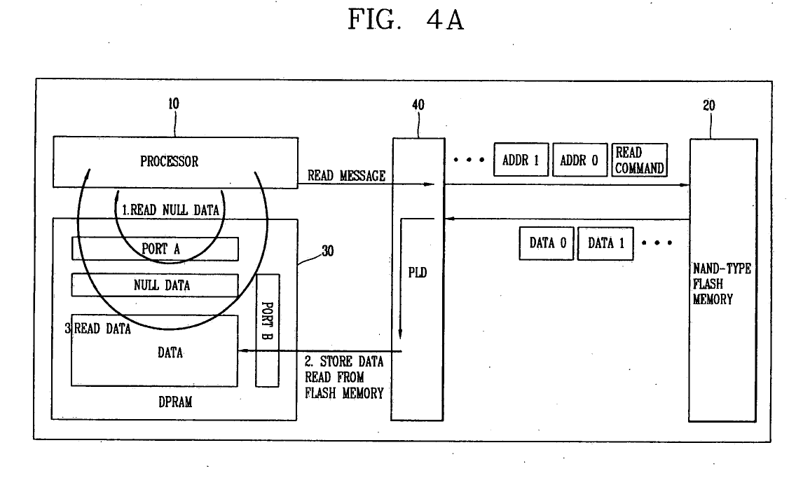

FIGS. 4A and 4B are block diagrams illustrating the memory device in accordance with an embodiment of the invention. FIG. 4A is a block diagram illustrating a data read operation of the present embodiment. FIG. 4B is a block diagram illustrating a data write operation of the present embodiment.

The memory device comprises a processor 10, a NAND-TYPE flash memory 20, and an interface circuit. The interface circuit comprises a DPRAM 30 and a PLD 40. The interface circuit connects the processor 10 and the NAND-TYPE flash memory 20. The DPRAM 30 processes a read/write cycle of the NAND-TYPE flash memory 20 at speeds comparable to static random access memory (SRAM), and performs operations accessing the NAND-TYPE flash memory 20. The PLD 40 provides a serial interface to the NAND-TYPE flash memory 20 to reduce the load of the processor 10, thereby reducing the data accessing time.

Referring to FIG. 4A, to perform a read operation, the processor 10 transmits a read message read data from an address of the NAND-TYPE flash memory 20′ to the PLD 40 by reading a null data from the specific address of the DPRAM 30, and performs other operations. The PLD 40 interprets the read message, generates a command/address instruction corresponding to the read message, reads the data from the NAND-TYPE flash memory 20, and stores the data in the DPRAM 30. After the data required by the processor 10 is read and stored in the DPRAM 30, the processor 10 reads the data stored in the DPRAM 10.

The PLD 40 interprets the read message using CS_A, OE_A, an upper address Addr_A[22:29], and a lower address Addr_A[0:15] in the interface of the DPRAM 30. CS_A denotes chip select of port A of the DPRAM 30 and OE_A denotes output enable of port A of the DRAM 30. The processor 10 accesses the DPRAM 30. The output enable of port A allows the processor 10 to read the data from the DPRAM 30. In addition, the PLD 40 interprets the read message by decoding the addresses from the processor 10 (for example, upper address Addr_A[22:29] and lower address Addr_A[0:15]).

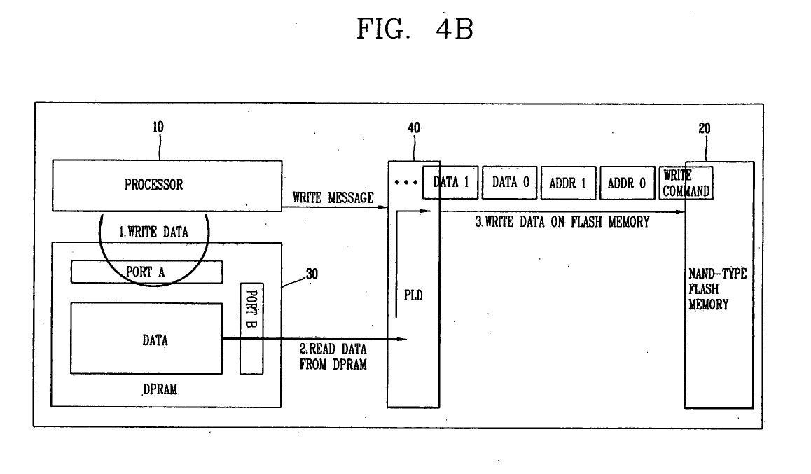

Referring to FIG. 4B, to perform the data write operation, the processor 10 transmits a write message “store data in the NAND-TYPE flash memory 20″ to the PLD 40 by storing data for recording in the NAND-TYPE flash memory 20 in the DPRAM 30. The processor 10 notifies data storage to the PLD 40 by using a signal/INT_B of the DPRAM 30 (see FIG. 5). Signal/INT_B denotes an output signal from the DPRAM 30 for notifying to the PLD 40 that the data has been stored in the DPRAM 30.

When receiving the signal/INT_B, the PLD 40 interprets the write message, generates a command/address instruction corresponding to the write message, reads the data stored in the DPRAM 30, and stores the data in the NAND-TYPE flash memory 20. The PLD 40 interprets the write message by using CS_A, WE_A, an upper address Addr_A[22:29] and a lower address Addr_A[0:15] of the DPRAM 30 (see FIG. 5).

The processor 10 reads the data stored in the NAND-TYPE flash memory 20 and stores the data in the NAND-TYPE flash memory 20. The processor reads the data from the DPRAM 30 and writes the data on the DPRAM 30. As such, while the PLD 40 controls the NAND-TYPE flash memory 20, the processor 10 is freed to perform other operations.

FIG. 5 is a block diagram illustrating the NAND-TYPE flash memory device in accordance with an embodiment of the invention.

In the interface of port A of the DPRAM 30, CS_A denotes a chip select of port A of the DPRAM 30, OE_A denotes output enable of port A of the DPRAM 30, WE_A denotes write enable of port A of the DPRAM 30, INT_A denotes interrupt of port A of the DPRAM 30, Addr_A[0:29] denotes an address of port A of the DPRAM 30, and D_A[0:15] denotes a data of port A of the DPRAM 30.

In the interface of port B of the DPRAM 30, CS_B denotes chip select of port B of the DPRAM 30, OE_B denotes output enable of port B of the DPRAM 30, WE_B denotes write enable of port B of the DPRAM 30, INT_B denotes interrupt of port B of the DPRAM 30, Addr_B[0:15] denotes an address of port B of the DPRAM 30, and D_B[0:8] denotes a data of port B of the DPRAM 30.

In the interface of the NAND-TYPE flash memory 20, FCE denotes flash memory chip enable, FWE denotes flash memory write enable, FOE denotes flash memory output enable, FCLE denotes flash memory command latch enable, FALE denotes flash memory address latch enable, I/O denotes an input/output port, and RY/BY denotes read/busy.

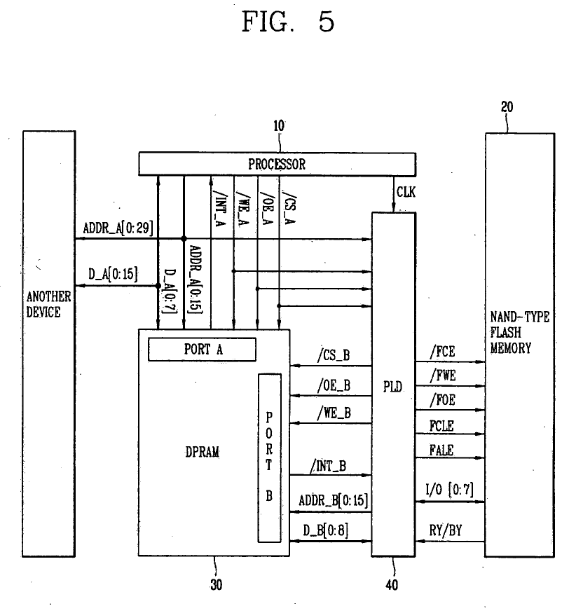

FIG. 6 is a block diagram illustrating the PLD 40 of the NAND-TYPE flash memory device in accordance with an embodiment of the invention.

The PLD 40 receives the read and write message from the processor 10. The PLD 40 interprets the messages, reads the data from the NAND-TYPE flash memory 20, and stores the data in the DPRAM 30. The PLC 35 reads the data stored in the DPRAM 30, and stores the data in the NAND-TYPE flash memory 20. In this manner, the PLC 35 controls the flow of data to and from the NAND-TYPE flash memory 20. The PLD 40 of FIG. 6 can be embodied in various forms based on the invention.

In accordance with yet another embodiment, a device for a mobile communication system, is disclosed, that stores, receives and transmits multimedia data comprising: a processor generating a read message or a write message for data; a first memory; means for connecting the first memory to the processor; a second memory; means for connecting the second memory between the first memory and the processor.

The first memory, the second memory, and the processor are selected so that when the processor transmits a read message and a write message, which is interpreted by the connecting means. The second memory, on the basis of the read message, transfers stored data to the first memory, and the first memory, on the basis of the write message, transfers stored data to the second memory. In one alternative, the first memory is a NAND-TYPE flash memory, the second memory is a dual-port random access, and the connecting means is a programmable logic device for interpreting the read and the write messages, for example.

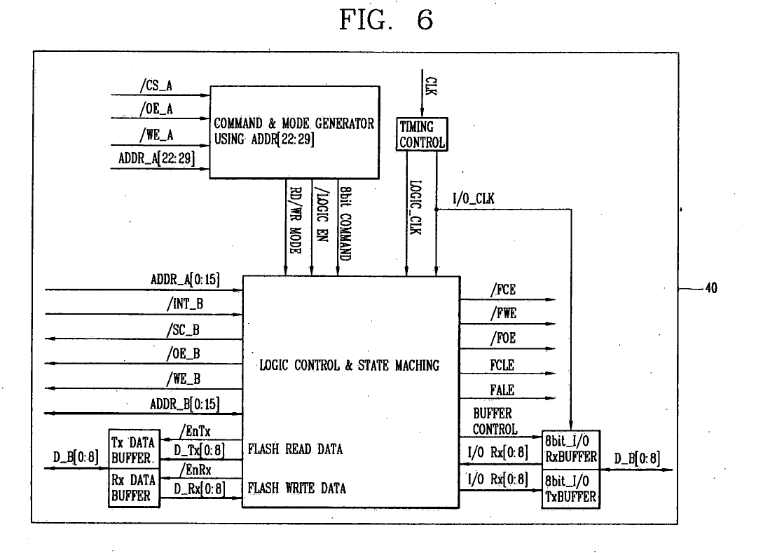

Referring to FIG. 7, a block diagram of a mobile communication device 700, such as a mobile phone, for performing the methods of the invention. The mobile communication device 700 comprises a processing unit 710 such as a microprocessor or digital signal processor, an RF module 735, a power management module 706, an antenna 740, a battery 755, a display 715, a keypad 720, a storage unit 730 such as flash memory, ROM or SRAM, a speaker 745 and a microphone 750.

In accordance with one embodiment, a user enters instructional information, such as a telephone number, for example, by pushing the buttons of a keypad 720 or by voice activation using the microphone 750. The processing unit 710 receives and processes the instructional information to perform the appropriate function, such as to dial the telephone number. Operational data may be retrieved from the storage unit 730 to perform the function. Furthermore, the processing unit 710 may display the instructional and operational information on the display 715 for the user's reference and convenience.

The processing unit 710 issues instructional information to the RF module 135, to initiate communication, for example, transmit radio signals comprising voice communication data. The RF module 735 comprises a receiver and a transmitter to receive and transmit radio signals. The antenna 740 facilitates the transmission and reception of radio signals. Upon receive radio signals, the RF module 735 may forward and convert the signals to baseband frequency for processing by the processing unit 710. The processed signals would be transformed into audible or readable information outputted via the speaker 745.

The processing unit 710 is adapted to perform the methods as illustrated above in the discussions related to FIGS. 4-6. As an example, the processing unit 710 is a flash memory device for receiving and transmitting packet data comprising: a processor for generating a read message or a write message; a dual-port random access memory (DPRAM); a NAND-TYPE flash memory; and a programmable logic device (PLD) for storing the data in the NAND-TYPE flash memory in the DPRAM on the basis of the read message, and storing the data in the DPRAM in the NAND-TYPE flash memory on the basis of the write message. Other features, as described above in FIGS. 4-6, may be incorporated into the processing unit 710.

The processing unit 710 stores the messages received from and messages transmitted to other users in the storage unit 730, receive a conditional request for message input by the user, process the conditional request to read data corresponding to the conditional request from the storage unit. The processing unit 710 outputs the message data to the display unit 715. The storage unit 730 is adapted to store message data of the messages both received and transmitted.

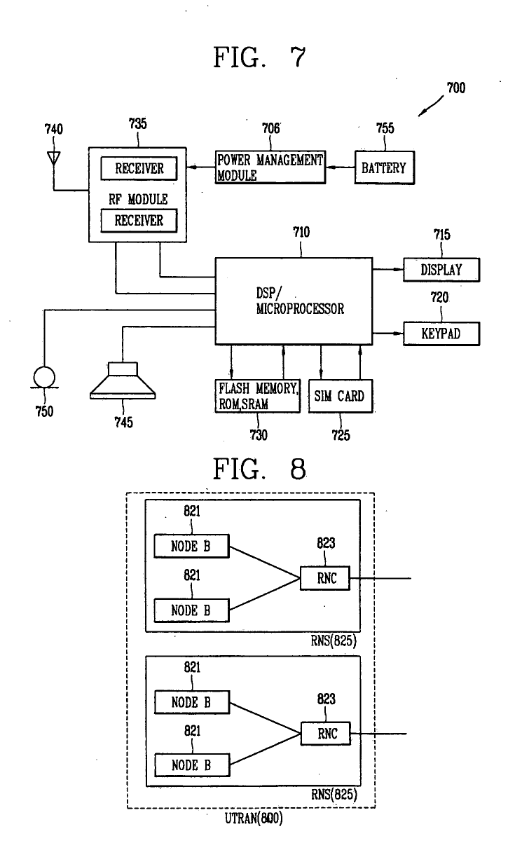

FIG. 8 illustrates a block diagram of a UTRAN 800 according to the preferred embodiment of the present invention. The UTRAN 700 includes one or more radio network sub-systems (RNS) 825. Each RNS 825 includes a radio network controller (RNC) 823 and a plurality of Node-Bs (base stations) 821 managed by the RNC. The RNC 823 handles the assignment and management of radio resources and operates as an access point with respect to the core network. Furthermore, the RNC 823 is adapted to perform the methods of the present invention.

The Node-Bs 821 receive information sent by the physical layer of the terminal 710 through an uplink, and transmit data to the terminal through a downlink. The Node-Bs 821 operate as access points, or as a transmitter and receiver, of the UTRAN 800 for the terminal. It will be apparent to one skilled in the art that the mobile communication device 800 may be readily implemented using, for example, the processing unit 710 (of FIG. 7) or other data or digital processing device, either alone or in combination with external support logic.

By utilizing the present invention, the user of a mobile communication device may store multimedia data as described above in FIGS. 4-6. As an example, the controller 810 controls a memory device used in a mobile terminal, comprising storing a data stored in a second memory in a first memory on the basis of a read message; and storing the data stored in the first memory in the second memory on the basis of a write message.

In other aspects, the data for recording on the second memory is stored in the first memory by the processor and the first memory is a dual-port random access memory (DPRAM). In yet another aspect, the second memory is a NAND-TYPE flash memory. The data stored in the second memory is stored in the first memory through a programmable logic device (PLD), and the data stored in the first memory is stored in the second memory through the PLD.

In yet another aspect, the data stored in a second memory in the first memory on the basis of the read message comprises generating the read message read data from a specific address of the second memory by reading a null data from the specific address of the first memory; and storing the data of the second memory in the first memory by generating a command/address instruction corresponding to the read message.

In yet another aspect, the storing the data stored in the first memory in the second memory on the basis of the write message comprising: generating the write message 'store data in the second memory by storing the data in the second memory in the first memory; and reading the data stored in the first memory by generating a command/address instruction corresponding to the write message and storing the read data in the second memory.

It will be apparent to one skilled in the art that the preferred embodiments of the present invention can be readily implemented using, for example, the processing unit 710 (of FIG. 7) or other data or digital processing device, either alone or in combination with external support logic.

Although the present invention is described in the context of mobile communication, the present invention may also be used in any wireless communication systems using mobile devices, such as PDAs and laptop computers equipped with wireless communication capabilities. Moreover, the use of certain terms to describe the present invention should not limit the scope of the present invention to certain type of wireless communication system, such as UMTS. The present invention is also applicable to other wireless communication systems using different air interfaces and/or physical layers, for example, TDMA, CDMA, FDMA, WCDMA, etc.

The preferred embodiments may be implemented as a method, apparatus or article of manufacture using standard programming and/or engineering techniques to produce software, firmware, hardware, or any combination thereof. The term “article of manufacture” as used herein refers to code or logic implemented in hardware logic (e.g., an integrated circuit chip, Field Programmable Gate Array (FPGA), Application Specific Integrated Circuit (ASIC), etc.) or a computer readable medium (e.g., magnetic storage medium (e.g., hard disk drives, floppy disks, tape, etc.), optical storage (CD-ROMs, optical disks, etc.), volatile and non-volatile memory devices (e.g., EEPROMs, ROMs, PROMs, RAMs, DRAMs, SRAMs, firmware, programmable logic, etc.).

Code in the computer readable medium is accessed and executed by a processor. The code in which preferred embodiments are implemented may further be accessible through a transmission media or from a file server over a network. In such cases, the article of manufacture in which the code is implemented may comprise a transmission media, such as a network transmission line, wireless transmission media, signals propagating through space, radio waves, infrared signals, etc. Of course, those skilled in the art will recognize that many modifications may be made to this configuration without departing from the scope of the present invention, and that the article of manufacture may comprise any information bearing medium known in the art.

The logic implementation shown in the figures described specific operations as occurring in a particular order. In alternative implementations, certain of the logic operations may be performed in a different order, modified or removed and still implement preferred embodiments of the present invention. Moreover, steps may be added to the above described logic and still conform to implementations of the invention.

The forgoing embodiments and advantages are merely exemplary and are not to be construed as limiting the present invention. The present teaching can be readily applied to other types of apparatuses. The description of the present invention is intended to be illustrative, and not to limit the scope of the claims. Many alternatives, modifications, and variations will be apparent to those skilled in the art. In the claims, means-plus-function clauses are intended to cover the structure described herein as performing the recited function and not only structural equivalents but also equivalent structures.

As the present invention may be embodied in several forms without departing from the spirit or essential characteristics thereof, it should also be understood that the above-described embodiments are not limited by any of the details of the foregoing description, unless otherwise specified, but rather should be construed broadly as defined in the appended claims. Therefore all changes and modifications that fall within the metes and bounds of the claims, or equivalence of such metes and bounds are therefore intended to be embraced by the appended claims.

1. A memory system for a mobile communication system that receives and transmits multimedia data utilizing a programmable logic device and a first memory and a second memory to reduce accessing time for data and load on a processor comprising:
a processor for generating at least one of a read message and write message for data;
a first memory for storing the data;
a second memory for storing the data received from the first memory; and
a programmable logic device electrically coupled to the processor, the first memory, and the second memory for interpreting the read or the write message.

2. The system of claim 1 wherein the first memory is a dual-port random access memory device comprising NAND-TYPE flash memory.

3. The system of claim 2 wherein the second memory is a NAND-TYPE flash memory device.

4. The system of claim 1 wherein the second memory transfers, based on a write message, data stored in the first memory to the second memory.

5. The system of claim 1 wherein the processor stores the data intended to be written from the second memory to the first memory.

6. The system of claim 1 wherein the processor reads the data intended to be read from the second memory to the first memory.

7. The system of claim 1 wherein the programmable logic device reads the data stored in the first memory, and writes the data in the second memory.

8. The system of claim 1 wherein the programmable logic device reads the data stored in the second memory, and writes the data in the first memory.

9. The system of claim 1 wherein the processor reads the data stored in the second memory, the processor transmits a read message to the programmable logic device by reading a null data from the specific address of the first memory, and the programmable logic device stores the data of the second memory in the first memory by generating a command/address instruction corresponding to the read message,
wherein if the data read from the second memory is stored in the first memory, the processor reads the data stored in the first memory.

10. The system of claim 9 wherein the second memory is a dual-port random access memory and the programmable logic device interprets the read message on the basis of upper and lower addresses of the dual-port random access memory.

11. The system of claim 3 wherein the processor stores the data in the NAND-TYPE flash memory and transmits a write message to the programmable logic device, storing the data for recording on the NAND-TYPE flash memory in the dual-port random access memory.

12. The system of claim 11 wherein the programmable logic device reads the data stored in the dual-port random access memory by generating a command/address instruction corresponding to the write message, and storing the data in the NAND-TYPE flash memory.

13. The system of claim 9 wherein the first memory is a dual-port random access memory and the programmable logic device interprets the message on the basis of upper and lower addresses of the dual-port random access memory.

14. A memory system for receiving and transmitting data for a mobile communications system, comprising:
a processor for generating at least one of a read message and a write message;
a first memory;
a second memory; and
an interface unit electrically coupled to the processor, the first memory, and a second memory for transmitting data stored in the second memory into the first memory on the basis of the read message, and transmitting the data stored in the first memory into the second memory on the basis of the write message.

15. A system of claim 14 wherein the first memory is a dual-port random access memory and the second memory is a NAND-TYPE flash memory.

16. The system of claim 14 wherein the processor stores the data intended to be written to the second memory in the first memory.

17. The system of claim 14 wherein the processor reads the data intended to be read from the second memory to the first memory.

18. The system of claim 14 wherein the interface unit for reading and storing the data is a programmable logic device.

19. The system of claim 14 wherein the processor stores the data in the second memory and transmits a write message to the interface unit for transmitting the data in the second memory to in the first memory, and the interface unit reads the data stored in the first memory by generating a command/address instruction corresponding to the write message, and stores the data in the second memory.

20. A method to control a memory in a mobile communication system for reading and writing multimedia communication signals, the method comprising:
transferring data on the basis of a read message stored in a second memory to a first memory; and
transferring the data on the basis of a write message stored in the first memory to the second memory.

21. The method of claim 20 wherein the data recorded on the second memory is stored in the first memory by a processor.

22. The method of claim 20 wherein the first memory is a NAND-TYPE flash memory.

23. The method of claim 20 wherein the second memory is a dual-port random access memory.

24. The method of claim 20 wherein the data stored in the second memory is stored in the first memory through a programmable logic device, and the data stored in the first memory is stored in the second memory through the programmable logic device.

25. The method of claim 20 wherein the step of storing the data on the basis of a read message further comprises:
generating the read message upon reading a null data from an address of the first memory; and
storing the data of the second memory in the first memory upon a command/address instruction corresponding to the read message.

26. The method of claim 20 wherein the step of storing the data on the basis of the write message further comprises:
generating the write message for transferring the data from the first memory to the second memory; and
reading the data stored in the first memory by generating a command/address instruction corresponding to the write message and storing the read data in the second memory.

27. A mobile communication device for managing messages received from and transmitted to another user by a user of the mobile communication device, the mobile communication device comprising:
an RF module which includes a transmitter to send the transmitted messages from a user and a receiver for receiving messages from another user; and a processing unit adapted to:
transferring data on the basis of a read message stored in a second memory to a first memory; and
transferring the data on the basis of a write message stored in the first memory to the second memory.

28. The mobile communication device of claim 27 wherein the step of transferring data on the basis of a read message further includes:
generating the read message upon reading a null data from a specific address of the first memory; and
storing the data of the second memory in the first memory upon a command/address instruction corresponding to the read message.

29. The mobile communication device of claim 27 wherein the step of transferring data packets on the basis of a write message further including:
generating the write message for transferring the data from the first memory to the second memory; and
reading the data stored in the first memory by generating a command/address instruction corresponding to the write message and storing the read data in the second memory.

30. The method of claim 27 wherein the first memory is a NAND-TYPE flash memory.

31. The method of claim 27 wherein the second memory is a dual-port random access memory.

32. A network for radio communication with a terminal in a mobile communication system, the network comprising:
at least one transmitter adapted to transmit a plurality of packet data to a terminal using assigned power levels;
at least one receiver adapted to receive an acknowledgement signal from the terminal, the acknowledgment signal indicating whether the transmitted packet data was correctly received; and
a controller adapted to:
transferring data on the basis of a read message stored in a second memory to a first memory; and
transferring the data on the basis of a write message stored in the first memory to the second memory.
